(19) United States
(12) Patent Application Publication
(10) Pub. No.: US 2024/0105470 A1
(43) Pub. Date: Mar. 28, 2024

(54) SUBSTRATE PROCESSING APPARATUS AND SEMICONDUCTOR DEVICE MANUFACTURING METHOD USING THE SAME

(71) Applicant: Samsung Electronics Co., Ltd., Suwon-si (KR)

(72) Inventors: Dong Il PARK, Suwon-si (KR); Sang-Woo JANG, Suwon-si (KR)

(73) Assignee: Samsung Electronics Co., Ltd., Suwon-si (KR)

(21) Appl. No.: 18/453,679

(22) Filed: Aug. 22, 2023

(30) Foreign Application Priority Data
Sep. 28, 2022 (KR) 10-2022-0122939

(51) Int. Cl. H01L 21/67; H01L 21/02; H01L 21/683

(52) U.S. Cl. CPC H01L 21/6708; H01L 21/02274; H01L 21/6719; H01L 21/6831

(57) ABSTRACT

A method may include loading a substrate into a substrate processing apparatus and performing a plasma treatment process on the substrate. The substrate processing apparatus includes a housing that defines a processing region, a power supply source on the housing and configured to generate plasma, a shower head in the housing and configured to supply the plasma to the processing region, an adapter between the power supply source and the shower head and separated from the shower head, a lid surrounding at least part of the adapter, and pads between the shower head and the lid. The shower head may include first fastening holes. The lid may be connected to the shower head through fastening portions respectively inserted into the first fastening holes. The pads may include polytetrafluoroethylene. At least a part of the pads may contact a bottom surface of the adapter.

### CROSS-REFERENCE TO RELATED APPLICATION

This application claims priority from Korean Patent Application No. 10-2022-0122939, filed on Sep. 28, 2022 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a substrate processing apparatus and a semiconductor device manufacturing method using the same.

### 2. Description of the Related Art

As semiconductor elements and the like become gradually highly integrated, the sizes of various patterns forming each element may be further miniaturized. In contrast to the trend toward miniaturization of the semiconductor element patterns, the size of the semiconductor wafers may become gradually larger from the viewpoint of improvement in productivity. Despite the miniaturization of patterns, the size of substrates such as semiconductor wafers and photomasks becomes gradually larger, the importance of uniformly forming and managing the element patterns formed repeatedly inside the enlarged semiconductor wafer or photomask at the entire positions of the substrate may gradually increase.

On the other hand, a baffle for evenly distributing plasma or radical toward the substrate, and a lid fastened to the baffle may be provided in an upper part of a process chamber. The baffle may adiabatically expand or adiabatically contract in a semiconductor process performed inside the process chamber. When the baffle adiabatically expands or adiabatically contracts, a defect may occur around a fastening portion between the baffle and the lid.

### SUMMARY

Aspects of the present disclosure provide a method of manufacturing a semiconductor device having improved yield.

Aspects of the present disclosure also provide a substrate processing apparatus having improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a method of manufacturing a semiconductor device may include loading a substrate into a substrate processing apparatus; and performing a plasma treatment process on the substrate. The substrate processing apparatus may include a housing that defines a processing region in which the substrate is processed, a power supply source on the housing and configured to generate plasma, a shower head in the housing and configured to supply the plasma to the processing region, an adapter between the power supply source and the shower head, a lid surrounding at least a part of the adapter, and a plurality of pads between the shower head and the lid. The shower head may include one or more first fastening holes. The adapter may be separated from the shower head. The lid may be connected to the shower head through one or more fastening portions respectively inserted into the one or more first fastening holes. Each of the plurality of pads may include polytetrafluoroethylene. At least a part of the plurality of pads may come into contact with a bottom surface of the adapter.

According to an embodiment of the present disclosure, a substrate processing apparatus may include a housing that defines a processing region in which a substrate is processed; a power supply source on the housing, the power supply source being configured to generate plasma; a shower head in the housing and configured to supply the plasma to the processing region, the shower head including one or more first fastening holes; an adapter between the power supply source and the shower head, the adapter being separated from the shower head; a lid surrounding at least a part of the adapter, the lid being connected to the shower head through one or more fastening portions respectively inserted into the one or more first fastening holes; and a plurality of pads between the shower head and the lid. Each of the plurality of pads may include polytetrafluoroethylene. At least a part of the plurality of pads may come into contact with a bottom surface of the adapter.

According to an embodiment of the present disclosure, a substrate processing apparatus may include a housing that defines a processing region in which a substrate is processed; a power supply source on the housing, the power supply source being configured to generate plasma; a shower head in the housing and configured to supply the plasma to the processing region, and the shower head including a plurality of first fastening holes; an adapter between the power supply source and the shower head, the adapter being separated from the shower head; a lid surrounding at least a part of the adapter, the lid being connected to the shower head through a fastening portion inserted into the plurality of first fastening holes, and the lid not being in contact with the shower head; and a plurality of pads between the lid and the shower head. The pads may include a horizontal portion and a vertical portion. The horizontal portion may extend in a horizontal direction and may come into contact with an upper surface of the shower head. The vertical portion may extend in a vertical direction and may come into contact with a side surface of the shower head.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view for explaining the substrate processing system according to some embodiments of the present disclosure.

FIG. 2 is a cross-sectional view for explaining the substrate processing apparatus according to some embodiments of the present disclosure.

FIG. 3 is an enlarged view of a region P of FIG. 2.

FIG. 4 is an enlarged view of a region Q1 of FIG. 3.

FIG. 5 is a plan view for explaining a shower head according to some embodiments.

FIG. 6 is a perspective view for explaining a pad according to some embodiments.

FIGS. 7 to 9 are diagrams for explaining the pad according to some embodiments.

FIG. 10 is a plan view for explaining the shower head according to some embodiments.

FIG. 11 is a perspective view for explaining the pad according to some embodiments.

FIG. 12 is a diagram for explaining the substrate processing apparatus according to some embodiments.

FIG. 13 is an enlarged view of a region Q2 of FIG. 12.

FIG. 14 is a diagram for explaining a substrate processing apparatus according to some embodiments.

FIG. 15 is an enlarged view of a region Q3 of FIG. 14.

FIG. 16 is a diagram for explaining the substrate processing apparatus according to some embodiments.

FIG. 17 is an enlarged view of a region Q4 of FIG. 16.

FIGS. 18 to 20 are diagrams for explaining a method of manufacturing a semiconductor device according to some embodiments.

### DETAILED DESCRIPTION OF THE EMBODIMENTS

Hereinafter, embodiments according to technical concepts of the present disclosure will be described with reference to the accompanying drawings.

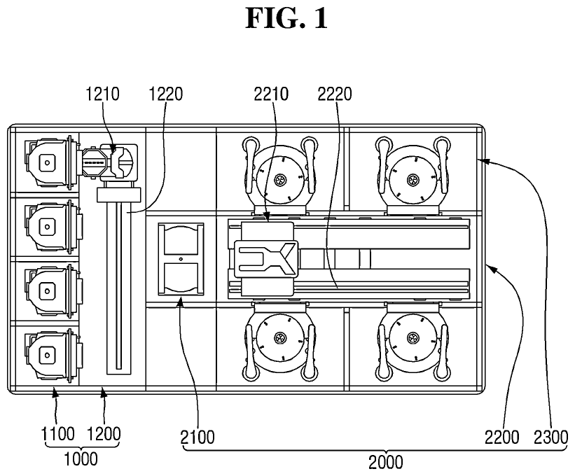

A substrate processing system according to some embodiments will be described below with reference to FIG. 1. FIG. 1 is a plan view for explaining the substrate processing system according to some embodiments of the present disclosure.

Referring to FIG. 1, the substrate processing system according to some embodiments may include an index module 1000 and a process module 2000.

The index module 1000 receives a substrate from the outside and transports the substrate to the process module 2000. The process module 2000 may perform at least one of a cleaning process, a deposition process, an etching process, and an ashing process. The index module 1000 may be an equipment front end module (EFEM). The index module 1000 may include a load port 1100 and a transport frame 1200.

The load port 1100 may accommodate the substrate. The substrate may be placed in a container inside the load port 1100. The container may use a front opening unified pod (FOUP). The container may be loaded into the load port 1100 from the outside by an overhead transfer (OHT). The container may be unloaded to the outside from the load port 1100 by the overhead transfer. The transport frame 1200 may transport the substrates between the container placed on the load port 1100 and the process module 2000.

The process module 2000 may be a module that actually performs the process. The process module 2000 may include a buffer chamber 2100, a transport chamber 2200, and a process chamber 2300. In some embodiments, the process chamber 2300 may be, but is not limited to, in the form of a tower including a plurality of chambers.

The buffer chamber 2100 provides a space in which the substrates transported between the index module 1000 and the process module 2000 temporarily stay. The buffer chamber 2100 may provide a buffer slot in which the substrate is located. A transport robot 2210 of the transport chamber 2200 may withdraw the substrate placed in the buffer slot and transport it to the processing chamber 2300. The buffer chamber 2100 may provide the plurality of buffer slots.

The transport chamber 2200 transports the substrate between the buffer chamber 2100 placed around it and the process chamber 2300. The transport chamber 2200 may include a transport robot 2210 and a transport rail 2220. The transport robot 2210 may move on the transport rail 2220 to transport the substrate.

In some embodiments, the process chamber 2300 may be a substrate processing apparatus. For example, at least one of a cleaning process, a deposition process, an etching process, and an ashing process may be performed inside the process chamber 2300. More specifically, although the ashing process using plasma and/or radical may be performed inside the process chamber 2300, example embodiments are not limited thereto.

Some of the process chambers 2300 may be placed on one side of the transport chamber 2200. Another part of the process chamber 2300 may be placed on the other side of the transport chamber 2200. That is, the plurality of process chambers 2300 may be placed to face each other on the different sides of the transport chamber 2200.

A plurality of process chambers 2300 may be provided in the process module 2000. The plurality of process chambers 2300 may be placed in a row on one side of the transport chamber 2200. However, technical concepts of the present disclosure are not limited thereto.

The placement of the process chambers 2300 is not limited to the above example, and may be changed in consideration of the footprint of the apparatus, the process efficiency, and the like.

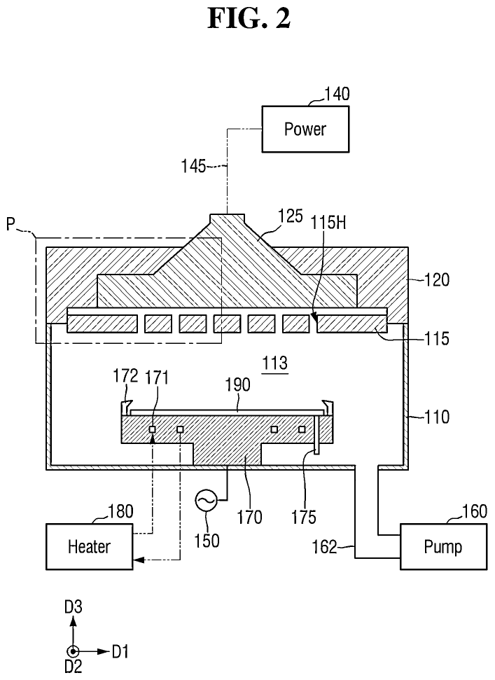

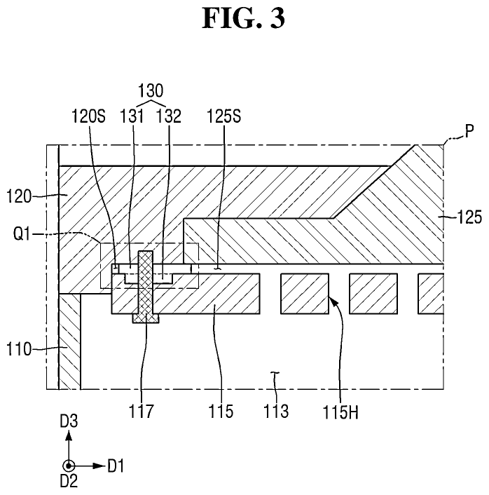

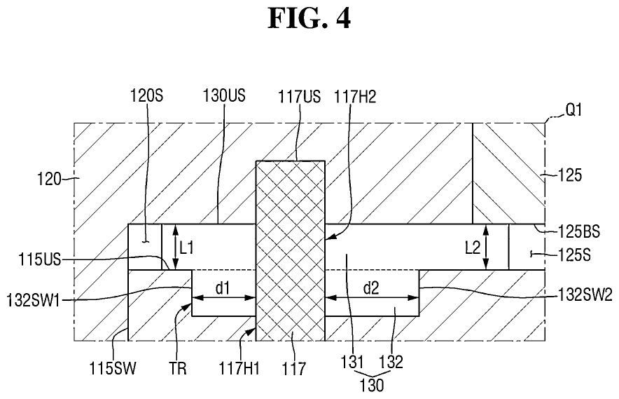

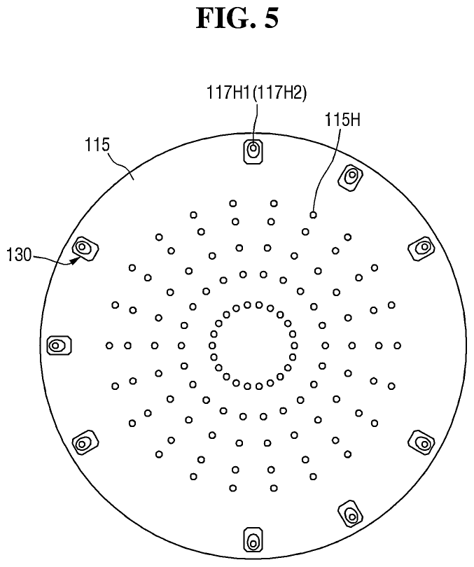

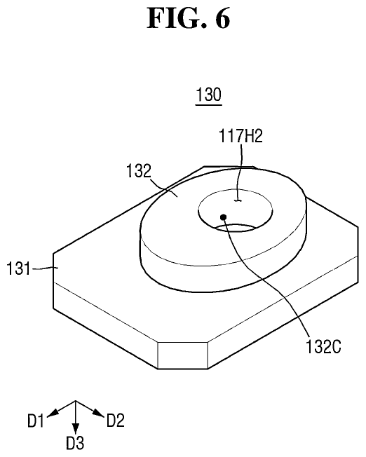

FIG. 2 is a cross-sectional view for explaining the substrate processing apparatus according to some embodiments of the present disclosure. FIG. 3 is an enlarged view of a region P of FIG. 2. FIG. 4 is an enlarged view of a region Q1 of FIG. 3. FIG. 5 is a plan view for explaining a shower head according to some embodiments. FIG. 6 is a perspective view for explaining a pad according to some embodiments.

Referring to FIGS. 2 to 6, the substrate processing apparatus according to some embodiments may include a housing 110, a shower head 115, a lid 120, an adapter 125, and a power supply source 140.

The substrate processing apparatus according to some embodiments may be a chamber for processing the substrate 190 using plasma and/or radical. For example, in the substrate processing apparatus, the substrate 190 may be subjected to a plasma treatment process. In an example, although the ashing process using plasma may be performed on the substrate 190, example embodiments are not limited thereto. According to the embodiments, the deposition process, the etching process, and the cleaning process may be performed together inside the substrate processing apparatus.

As used herein, the term “substrate” may mean the substrate itself, or a stacked structure including the substrate and a desired and/or alternatively predetermined layer or film formed on the surface thereof. Also, the “surface of the substrate” may mean an exposed surface of the substrate itself, or an exposed surface of a desired and/or alternatively predetermined layer or film formed on the substrate. For example, the substrate may be a wafer or may include the wafer and at least one material film on the wafer. The material film may be an insulating film and/or a conductive film formed on the wafer through various methods such as deposition, coating, and plating. For example, the insulating film may include an oxide film, a nitride film, an oxynitride film, and the like, and the conductive film may include a metal film, a polysilicon film, and the like. On the other hand, the material film may be a single film or multiple films formed on the wafer. Also, the material film may be formed on the wafer to have a desired and/or alternatively predetermined pattern.

The housing 110 may define a processing region 113. More specifically, the housing 110, the shower head 115, and the lid 120 may define the processing region 113. The processing region 113 is a region in which the substrate 190 is processed. The processing region 113 may be sealed from the outside. An overall external structure of the housing 110 may have a cylindrical shape, an elliptical pillar shape or a polygonal pillar shape. The housing 110 is generally formed of a metal material, and may be kept in an electrically grounded state to block noise from the outside at the time of the plasma process.

Although not shown, a liner may be provided inside the housing 110. The liner protects the housing 110 and may cover the metal structures inside the housing 110 to limit and/or prevent an occurrence of metal contamination caused by internal arcing. On the other hand, the liner may be formed of a metal material such as aluminum, a ceramic material, or the like. Also, the liner may be formed of a plasma-resistant material film. Here, the plasma-resistant material film may be, for example, an yttrium oxide (Y₂O₃) film. However, the plasma-resistant material film is not limited to the yttrium oxide film.

The housing 110 may be connected to an exhaust pump 160 through a discharge pipe 162. By-products after the plasma processing may be discharged through the exhaust pipe 162 using the exhaust pump 160. The exhaust pump 160 may also function of controlling the pressure inside the housing 110.

The shower head 115 may be installed inside the housing 110. The shower head 115 may include a plurality of plasma holes 115H through which a gas may flow. The plasma supplied from the outside of the housing 110 may be evenly distributed to the processing region 113 through the plasma holes 115H of the shower head 115.

The power supply source 140 may be installed outside the housing 110. The power supply source 140 may generate plasma and/or radical and supply plasma and/or radical to the processing region 113. For example, the power supply source 140 may supply plasma and/or radical to the processing region 113 through a plasma supply line 145. The plasma and/or radical are supplied to the processing region 113 via an adapter 125 to be described later and the shower head 115. The power supply source 140 may apply power to the gas to generate plasma and/or radical. The power may be applied, for example, in the form of radio frequency (RF) power (RF power) in the form of electromagnetic waves having a desired and/or alternatively predetermined frequency and intensity. Furthermore, the power has an on-off cycle in the form of electromagnetic waves, and may be applied in the form of continuous waves or in the form of pulses. The power supply source 145 may include power generation circuitry, such as an RF generator.

For reference, the plasma may include various components such as radical, ions, electrons, and ultraviolet rays. At least one of the constituents such as radical, ions, electrons, and ultraviolet rays may be utilized in the processing of the substrate 190, for example, etching, cleaning, deposition, and ashing processes. Basically, the radicals are electrically neutral and ions electrically have polarity. Therefore, the radicals may be used to isotropically remove a cleaning and ashing target in the cleaning and ashing process using the plasma, or to isotropically remove an etching target in the etching process using the plasma. Additionally, the radicals may also be used to hinder or suppress the deposition of particular constituents in the deposition process.

The adapter 125 may be placed between the power supply source 140 and the shower head 115. The adapter 125 may be a movement path of plasma and/or radical supplied from the power supply source 140. The plasma and/or radical generated by the power supply source 140 pass through the adapter 125 and are supplied to the shower head 115. The adapter 125 has a structure in which a lower area is widest, and the area gradually decreases from the bottom to the top. That is, the adapter 125 has a structure in which the area of the portion facing the power supply source 140 is smallest and the area of the portion facing the shower head 115 is largest.

In FIG. 3, the adapter 125 may be spaced apart from the shower head 115 in a third direction D3. An empty space may be generated between the adapter 125 and the shower head 115 (see reference numeral 125S). That is, the adapter 125 does not come into contact with the shower head 115. In some embodiments, a pad 130 may be placed between a lid 120 to be described below and the shower head 115. The pad 130 has a thickness in the third direction D3. The adapter 125 and the shower head 115 do not come into contact with each other by the pad 130.

In this specification, a first direction D1, a second direction D2, and the third direction D3 may intersect each other. The first direction D1 and the second direction D2 may be a horizontal direction, and the third direction D3 may be a vertical direction.

In some embodiments, the adapter 125 may be formed of a metal material such as aluminum (Al). The shower head 115 may also be formed of a metal material such as aluminum (Al). When the adapter 125 and the shower head 115 come into contact with each other, there is a high possibility that a defect occurs on a contact surface between the adapter 125 and the shower head 115. However, in the substrate processing apparatus of the present disclosure, the adapter 125 and the shower head 115 do not come into contact with each other. The probability of defect occurring between the adapter 125 and the shower head 115 may decrease accordingly.

In FIG. 2 again, the lid 120 may be placed on the housing 110. The lid 120 may wrap at least a part of the adapter 125. The lid 120 may wrap a part of the side wall of the shower head 115. The adapter 125 may protrude in the third direction D3 from the upper surface of the lid 120, but is not limited thereto. The lid 120 may be formed of, but is not limited to, a metal material such as aluminum (Al).

The lid 120 is generally formed of a metal material, and may be kept in an electrically grounded state to block external noise at the time of the plasma process. Although not shown, a liner may be provided inside the lid 120. The liner protects the lid 120, and may cover the metal structures inside the lid 120 to limit and/or prevent metal contamination from occurring due to the internal arcing. On the other hand, the liner may be formed of a metal material such as aluminum, a ceramic material, or the like. Also, the liner may be formed of a plasma-resistant material film. Here, the plasma-resistant material film may be, for example, an yttrium oxide (Y₂O₃) film. However, the plasma-resistant material film is not limited to the yttrium oxide film.

In FIGS. 3 and 4, the lid 120 and the shower head 115 may be connected to each other through a fastening portion 117. The fastening portion 117 may penetrate the shower head 115 and the pad 130. The fastening portion 117 may be placed inside a first fastening hole 117H1 of the shower head 115, and may be placed inside a second fastening hole 117H2 of the pad 130. The fastening portion 117 may protrude from the upper surface 130US of the pad 130 in the third direction D3. The level of the upper surface 117US of the fastening portion 117 may be different from the level of the upper surface 130US of the pad 130. For example, a vertical distance from the upper surface 115US of the shower head 115 to the upper surface 117US of the fastening portion 117 may be greater than a vertical distance from the upper surface 115US of the shower head 115 to the upper surface 130US of the pad 130. Also, at least a part of the fastening portion 117 may be placed inside the lid 120. That is, the fastening portion 117 may overlap the lid 120 in the first direction D1 and the second direction D2. The fastening portion 117 may overlap the lid 120 in the horizontal direction.

In some embodiments, the pad 130 may be placed between the lid 120 and the upper surface 115US of the shower head 115. The pad 130 may also be placed between the upper surface 115US of the shower head 115 and the adapter 125.

The pad 130 may include a horizontal portion 131 and a vertical portion 132. The horizontal portion 131 extends in the horizontal direction, for example, in the first direction D1 and the second direction D2. The vertical portion 132 extends in the vertical direction, for example, the third direction D3. The vertical portion 132 may protrude from the horizontal portion 131 in the third direction D3.

In some embodiments, the vertical portion 132 of the pad 130 may be placed inside the trench TR in the shower head 115. A depth of the trench TR is smaller than the thickness of the shower head 115 in the third direction D3. That is, the vertical portion 132 of the pad 130 completely overlaps the shower head 115 in the first direction D1 and the second direction D2. Also, a part of the shower head 115 does not overlap the vertical portion 132 in the first direction D1 and the second direction D2. The horizontal portion 131 of the pad 130 is placed on the vertical portion 132. The horizontal portion 131 is placed on the upper surface 115US of the shower head 115. From a planar viewpoint, the width of the cross section of the trench TR is larger than the width of the cross section of the first fastening hole 117H1.

In FIG. 6, the shape of the vertical portion 132 of the pad 130 is not circular from the planar viewpoint.

As an example, from the planar viewpoint, the vertical portion 132 may have an elliptical shape. However, technical concepts of the present disclosure are not limited thereto. From the planar viewpoint, since the shape of the vertical portion 132 of the pad 130 is not circular, when the pad 130, the shower head 115, and the lid 120 are coupled together through the fastening portion 117, the pad 130 may be fixed more stably.

The pad 130 may include a second fastening hole 117H2. The second fastening hole 117H2 may penetrate both the horizontal portion 131 and the vertical portion 132. The fastening portion 117 may be inserted into the second fastening hole 117H2. The pad 130, the lid 120 and the shower head 115 may be connected to each other through the fastening portion 117.

In some embodiments, the second fastening hole 117H2 may be offset from a center 132C of the vertical portion 132. The center 132C of the vertical portion 132 may be the center of gravity of the cross section of the vertical portion 132 from the planar viewpoint. Since the second fastening hole 117H2 is offset from the center 132C of the vertical portion 132, when the pad 130, the shower head 115, and the lid 120 are coupled together through the fastening portion 117, the pad 130 may be fixed more stably.

In FIG. 4 again, the vertical portion 132 of the pad 130 includes a first side wall 132SW1 and a second side wall 132SW2 that are opposite to each other. A first distance d1 from the first side wall 132SW1 to the fastening portion 117 is different from a second distance d2 from the second side wall 132SW2 to the fastening portion 117. Although the first distance d1 is shown to be smaller than the second distance d2, this is only for convenience of explanation and example embodiments are not limited thereto.

In some embodiments, at least a part of the pad 130 may come into contact with the bottom surface 125BS of the adapter 125. At least a part of the pad 130 may overlap the adapter 125 in the third direction D3. At least a part of the pad 130 may be placed between the adapter 125 and the shower head 115. As a result, the probability of occurrence of defect due to friction between the adapter 125 and the shower head 115 may decrease.

In some embodiments, a first vertical length L1 from the upper surface 115US of the shower head 115 to the upper surface 130US of the pad 130 is the same as a second vertical length L2 from the upper surface 115US of the shower head 115 to the lower surface 125BS of the adapter 125. That is, the thickness of the horizontal portion 131 of the pad 130 in the third direction D3 is the same as the thickness of the empty space 125S between the adapter 125 and the shower head 115 in the third direction D3. However, technical concepts of the present disclosure are not limited thereto.

In some embodiments, an empty space may also be generated between the lid 120 and the shower head 115 (see reference numeral 120S). One side wall of the pad 130 may not be placed on the same plane as the side wall 115SW of the shower head 115. An end of the upper surface 115US of the shower head 115 may be exposed. The exposed end of the upper surface 115US of the shower head 115 and the lid 120 do not come into contact with each other due to the pad 130. Therefore, the empty space 120S may be generated between the exposed end of the upper surface 115US of the shower head 115 and the lid 120.

In some embodiments, the lid 120 may come into contact with a part of the side wall 115SW of the shower head 115, but is not limited thereto.

The pad 130 may be made of a material that has a heat resistance, a chemical resistance, and a low coefficient of friction. That is, the pad 130 may be formed of materials that are heat resistant and resistant to chemicals. In an example, the pad 130 may be formed of Teflon. The Teflon may be polytetrafluoroethylene (PTFE). The Teflon has excellent heat resistance, corrosion resistance and abrasion resistance. The Teflon also has high heat resistance and hardly deforms by heat. In another example, the pad 130 may include Teflon combined with carbon (C). However, technical concepts of the present disclosure are not limited thereto.

Since the pad 130 may be placed between the lid 120 and the shower head 115, the lower surface of the lid 120 and the upper surface 115US of the shower head 115 do not come into contact with each other. Therefore, it is possible to limit and/or minimize the occurrence of defect that occurs when the lid 120 and the shower head 115 come into contact with each other.

In FIG. 5, the shower head 115 may include a plurality of first fastening holes 117H1. For example, the number of the first fastening holes 117H1 may be nine, but is not limited thereto. The first fastening holes 117H1 may be placed in the edge region of the shower head 115. Meanwhile, the plasma hole 115H may be placed in a center region of the shower head 115.

In some embodiments, the single pad 130 may correspond to the single first fastening hole 117H1. The single pad 130 may cover the single first fastening hole 117H1. However, technical concepts of the present disclosure are not limited thereto.

In FIG. 2 again, a substrate support unit 170 may be installed inside the housing 110. The substrate support unit 170 may be placed below the processing region 113 inside the housing 110. The substrate support 170 may support the substrate 190.

The substrate support 170 may include an electrostatic chuck configured to support the substrate 190 by electrostatic force, and a chuck support that supports the electrostatic chuck. The electrostatic chuck may include electrodes for chucking and dechucking the substrate 190 therein. The chuck support supports the electrostatic chuck placed thereon, and may be formed of a metal such as aluminum or a ceramic insulator such as alumina. A heating member, such as a heater, may be placed inside the chuck support, and heat from the heater may be transferred to the electrostatic chuck or the substrate 190. Also, power application wiring connected to the electrodes of the electrostatic chuck may be placed on the chuck support. However, the configuration of the substrate support unit 170 is not limited thereto, and the substrate support unit 170 may include a vacuum chuck configured to support the substrate 190 using a vacuum, or may be configured to support the substrate 190 mechanically.

The substrate support unit 170 may include at least one lift pin 175. The lift pin 175 may be configured to lift up the substrate 190 from the surface of the substrate support unit 170 upon which the substrate 190 sits. The lift pin 175 may be accommodated in the hole provided in the substrate support 170. The lift pin 175 may be provided to be movable in the vertical direction (the third direction D3) with respect to the substrate support unit 170. The lift pin 175 may move in the vertical direction (the third direction D3) to move the substrate 190 up and down. The substrate support unit 170 may include the lift pins 175 of the number suitable for supporting the substrate 190. For example, the substrate support unit 170 may include, but is not limited to, three or more lift pins 175 that are evenly spaced along a circumferential direction of the substrate support unit 170.

The lift pins 175 may be in a pin-up state of protruding upward from the substrate support unit 170 to support the substrate 190, when the substrate 190 to be processed is loaded into the substrate processing apparatus or the substrate 190 is unloaded from the substrate processing apparatus. Also, the lift pins 175 may be in a pin-down state of being lowered below the upper surface of the substrate support unit 170 so that the substrate 190 is placed on the substrate support unit 170, while the substrate 190 is being processed in the housing 110.

An RF bias source 150 may be connected to the substrate support unit 170. The RF bias source 150 may apply a RF power to the substrate support unit 170. In some embodiments, the RF bias source 150 may apply the RF power of low frequency less than about 200 kHz to the substrate support unit 170, while the cleaning process, the deposition process, the ashing process and/or the etching process on the substrate 190 is being performed. In some embodiments, the RF bias source 150 may remove the RF power supplied to the substrate support unit 170, while the cleaning process, the deposition process, the ashing process and/or the etching process on the substrate 190 is being performed.

In some embodiments, the substrate support unit 170 may further include a heating member 171 and a rim 172.

The heating member 171 may be connected to the heater 180. The heater 180 may heat the substrate support unit 170. The heater 180 may supply heat to the heating member 171 of the substrate support unit 170. The heater 180 may control the amount of heat supplied through the heating member 171 to control the temperature of the substrate support unit 170 and the temperature of the substrate 190 mounted on the substrate support unit 170. The heater 180 may include a resistive heating circuit, but is not limited thereto.

The rim 172 may be provided on the substrate support unit 170. The rim 172 may wrap the substrate 190 placed on the substrate support unit 170. The rim 172 may limit and/or prevent the substrate 190 from sliding on the substrate support unit 170. The rim 172 may include a ceramic material. Since the rim 172 includes a ceramic material, it may be vulnerable to a reactive stress.

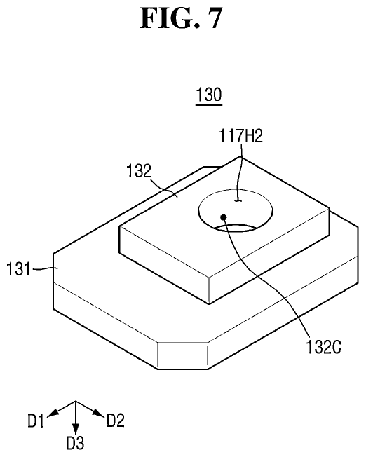

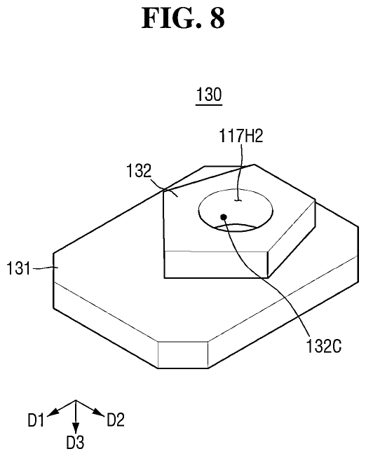

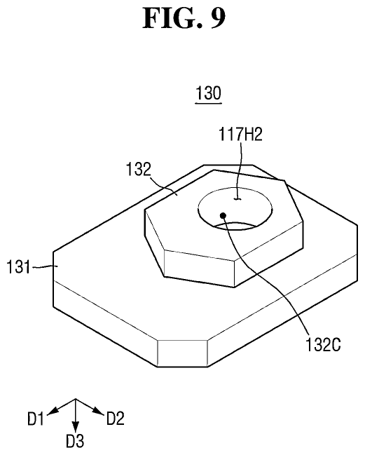

Various embodiments according to technical concepts of the present disclosure will be described below. FIGS. 7 to 9 are diagrams for explaining the pad according to some embodiments. For convenience of explanation, repeated contents of those explained using FIGS. 2 to 6 will be omitted.

Referring to FIGS. 7 to 9, in some embodiments, the shape of the vertical portion 132 of the pad 130 may not be elliptical from the planar viewpoint. For example, from the planar viewpoint, the shape of the vertical portion 132 of the pad 130 may be square, pentagonal or hexagonal. From the planar viewpoint, since the shape of the vertical portion 132 of the pad 130 is square, pentagonal or hexagonal, when the pad 130, the shower head 115 and the lid 120 are coupled together through the fastening portion 117, the pad 130 may be stably placed.

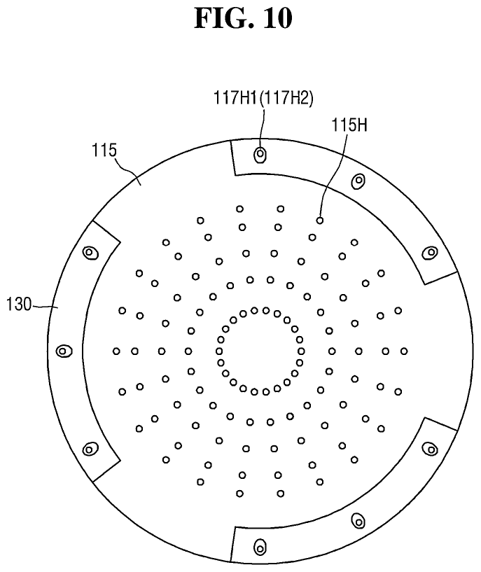

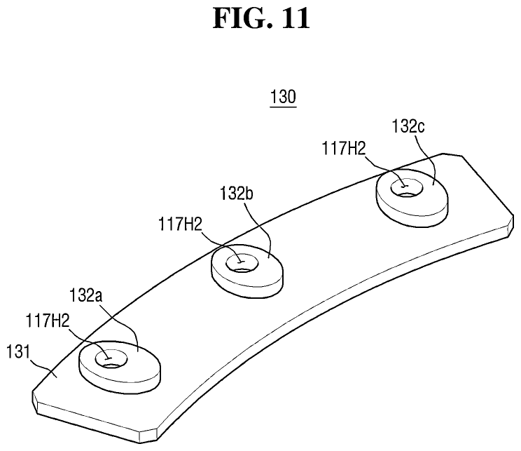

FIG. 10 is a plan view for explaining the shower head according to some embodiments. FIG. 11 is a perspective view for explaining the pad according to some embodiments. For convenience of explanation, repeated contents of those explained using FIGS. 2 to 6 will be omitted.

Referring to FIGS. 10 and 11, the single pad 130 may correspond to a plurality of first fastening holes 117H1. For example, the single pad 130 may cover three first fastening holes 117H1.

In FIG. 11, the pad 130 may include a horizontal portion 131 and first to third sub-vertical portions 132a, 132b and 132c. Each of the first to third sub-vertical portions 132a, 132b and 132c may include a second fastening hole 117H2. Each second fastening hole 117H2 may correspond to each of the first fastening holes 117H1.

In some embodiments, the second fastening hole 117H2 placed inside the first sub-vertical portion 132a is offset from the center of the first sub-vertical portion 132a. The second fastening hole 117H2 placed in the second sub-vertical portion 132b is offset from the center of the second sub-vertical portion 132b. The second fastening hole 117H2 placed in the third sub-vertical portion 132c is offset from the center of the third sub-vertical portion 132c.

From the planar viewpoint, cross-sections of each of the first to third sub-vertical portions 132a, 132b and 132c may have the same shape. For example, from the planar viewpoint, the cross-sectional shapes of each of the first to third sub-vertical portions 132a, 132b and 132c may be elliptical. However, technical concepts of the present disclosure are not limited thereto. From the planar viewpoint, the cross-sectional shapes of the first to third sub-vertical portions 132a, 132b and 132c may be different from each other.

In some embodiments, the side walls of the horizontal portion 131 of the pad 130 may not be straight. The side walls of the horizontal portion 131 of the pad 130 may be curved. For example, the side walls of the horizontal portion 131 may be recessed with respect to the center of the shower head 115.

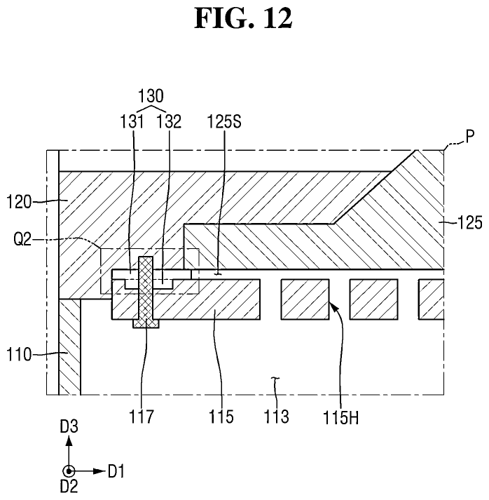

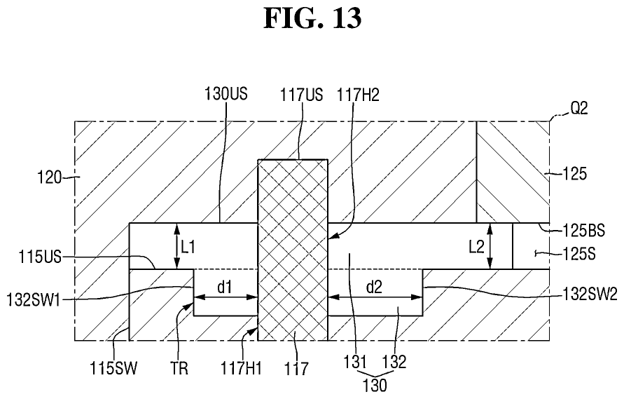

FIG. 12 is a diagram for explaining the substrate processing apparatus according to some embodiments. FIG. 13 is an enlarged view of a region Q2 of FIG. 12. For convenience of explanation, repeated contents of those explained using FIGS. 2 to 6 will be omitted.

Referring to FIGS. 12 and 13, one side wall of the pad 130 may be placed on the same plane as the side wall 115SW of the shower head 115. There may be no empty space (120S of FIG. 4) between the upper surface of the pad 130 and the lid 120. Also in this case, the lid 120 and the side wall 115SW of the shower head 115 may come into contact with each other.

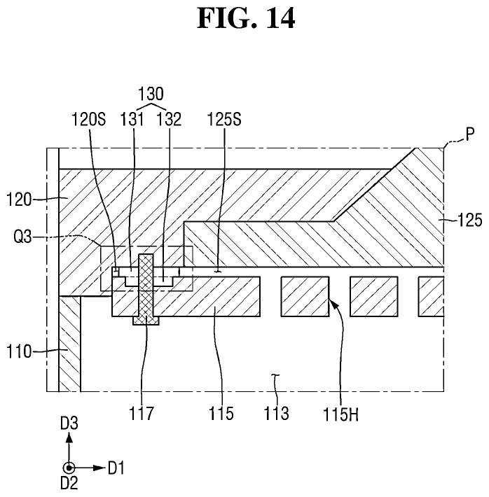

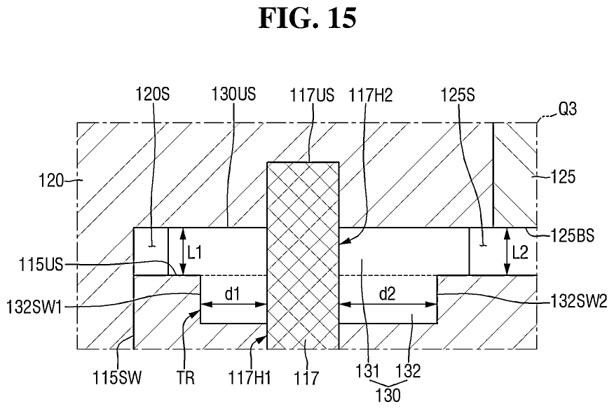

FIG. 14 is a diagram for explaining a substrate processing apparatus according to some embodiments. FIG. 15 is an enlarged view of a region Q3 of FIG. 14. For convenience of explanation, repeated contents of those explained using FIGS. 2 to 6 will be omitted.

Referring to FIGS. 14 and 15, the pad 130 may not come into contact with the bottom surface 125BS of the adapter 125. The pad 130 may not completely overlap the adapter 125 in the third direction D3. In an embodiment, the size of the horizontal portion 131 of the pad 130 may further decrease. Therefore, the pad 130 may not overlap the adapter 125 in the third direction D3.

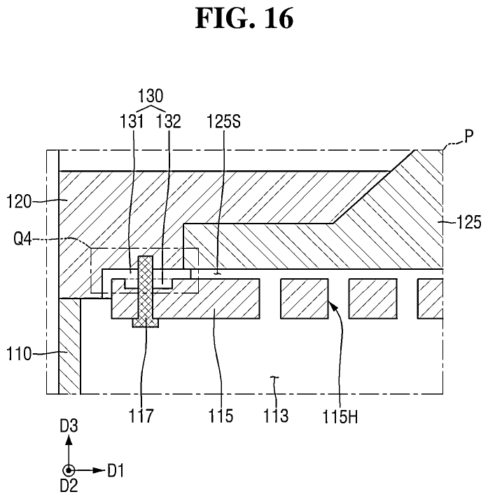

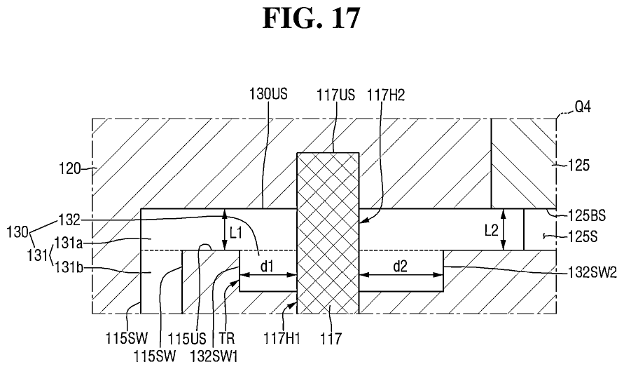

FIG. 16 is a diagram for explaining the substrate processing apparatus according to some embodiments. FIG. 17 is an enlarged view of a region Q4 of FIG. 16. For convenience of explanation, repeated contents of those explained using FIGS. 2 to 6 will be omitted.

Referring to FIGS. 16 and 17, the horizontal portion 131 of the pad 130 may include a first portion 131a and a second portion 131b.

The first portion 131a of the horizontal portion 131 extends along the upper surface 115US of the shower head 115. The second portion 131b of the horizontal portion 131 extends from the first portion 131a of the horizontal portion 131 in the third direction D3. The second portion 131b of the horizontal portion 131 extends along the side wall 115SW of the shower head 115. That is, the pad 130 may be placed between the lid 120 and the side wall 115SW of the shower head 115. Accordingly, the side wall 115SW of the shower head 115 and the lid 120 may not come into contact with each other. The probability of occurrence of defect on the side wall 115SW of the shower head 115 may decrease.

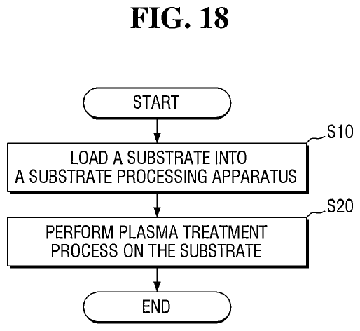

FIGS. 18 to 20 are diagrams for explaining a method of manufacturing a semiconductor device according to some embodiments.

Referring to FIGS. 18 to 20, the method of manufacturing the semiconductor device using the substrate processing apparatus according to the present disclosure may include loading (S10) of the substrate into the substrate processing apparatus, and performing (S20) of a plasma treatment process on the substrate.

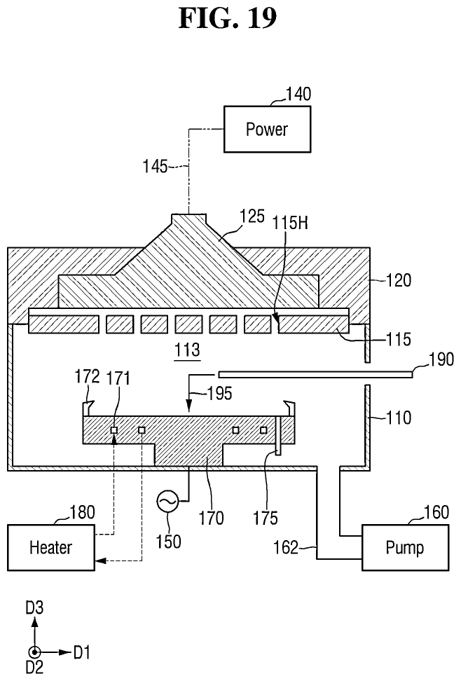

For example, in FIG. 19, the substrate 190 may be loaded into the substrate processing apparatus (see reference numeral 195). The substrate 190 may be loaded into the processing region 113 and placed on the substrate support unit 170. The housing 110 may include a gate valve that may be opened to load the substrate 190 into the substrate processing apparatus, closed while processing the substrate 190 in the substrate processing apparatus, and opened to remove the substrate 190 from the substrate processing apparatus after processing.

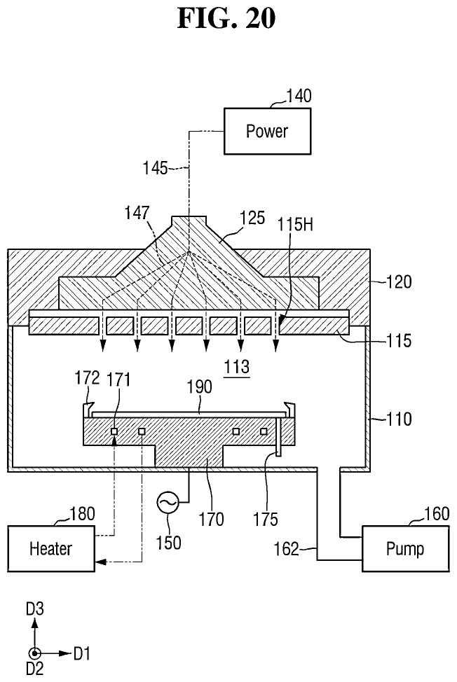

Subsequently, in FIG. 20, the plasma may be applied to the process region 113 (see reference numeral 147). First, the plasma is generated in the power supply source 140. The generated plasma is provided to the adapter 125 through the plasma supply line 145. Inside the adapter 125, the plasma may be dispersed into the plasma holes 115H of the shower head 115 (see reference numeral 147). The shower head 115 may evenly supply the plasma to the processing region 113.

A plasma treatment process may be performed on the substrate 190 using the plasma inside the processing region 113. The plasma treatment process may be, for example, but is not limited to, an ashing process.

The shower head 115 may expand adiabatically or contract adiabatically, while the plasma treatment process according to some embodiments is being performed. When the shower head 115 expands adiabatically or contracts adiabatically, a defect may occur at a boundary between the shower head 115 and the lid 120 or a boundary between the shower head 115 and the adapter 125. However, in the substrate processing apparatus of the present disclosure, the shower head 115 and the lids 120 do not come into contact with each other, due to the pad 130 placed between the shower head 115 and the lids 120. Also, the shower head 115 is spaced apart from the adapter 125 so that they do not come into contact with each other. Therefore, it is possible to reduce the probability of occurrence of defect at the boundary between the shower head 115 and the lid 120 or the boundary between the shower head 115 and the adapter 125. As a result, the yield of the semiconductor device to be manufactured using the substrate processing apparatus of the present disclosure can be improved.

Although not illustrated, operations of the substrate processing apparatuses according to example embodiments may be controlled by a controller. The controller may include processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The controller may operate in response to control signals, commands, and/or instructions input thereto from an external source (e.g., host). The controller may execute instructions stored in a memory for controlling operations of the substrate processing apparatuses according to example embodiments described herein.

While some example embodiments of the present disclosure have been described above with reference to the accompanying drawings, inventive concepts may be implemented in various different forms. Those skilled in the art to which the present disclosure pertains may understand that embodiments of inventive concepts may be implemented in other specific forms without departing from the spirit and scope of inventive concepts. Therefore, it should be understood that the example embodiments described above are illustrative in all aspects and not restrictive.

What is claimed is:

1. A method of manufacturing a semiconductor device, the method comprising:
loading a substrate into a substrate processing apparatus; and
performing a plasma treatment process on the substrate, wherein
the substrate processing apparatus includes
a housing that defines a processing region in which the substrate is processed,
a power supply source on the housing and configured to generate plasma,
a shower head in the housing and configured to supply the plasma to the processing region,
an adapter between the power supply source and the shower head,
a lid surrounding at least a part of the adapter, and
a plurality of pads between the shower head and the lid, wherein
the shower head includes one or more first fastening holes,
the adapter is separated from the shower head,
the lid is connected to the shower head through one or more fastening portions respectively inserted into the one or more first fastening holes,
each of the plurality of pads includes polytetrafluoroethylene, and
at least a part of the plurality of pads comes into contact with a bottom surface of the adapter.

2. The method of manufacturing the semiconductor device of claim 1, wherein
each of the plurality of pads includes a second fastening hole that overlaps a corresponding first fastening hole into which a corresponding fastening portion is inserted,
the corresponding first fastening hole is among the one or more first fastening holes, and
the corresponding fastening portion is among the one or more fastening portions.

3. The method of manufacturing the semiconductor device of claim 1, wherein
the shower head includes a trench,
each of the plurality of pads includes a first portion on the shower head and a second portion in the trench, and
a shape of the second portion is elliptical from a planar viewpoint.

4. The method of manufacturing the semiconductor device of claim 3, wherein
the one or more first fastening holes include a corresponding first fastening hole that corresponds with a corresponding pad among the plurality of pads, and
the corresponding first fastening hole is offset from a center of the second portion of the corresponding pad.

5. The method of manufacturing the semiconductor device of claim 1, wherein a part of the plurality of pads covers a part of a side wall of the shower head.

6. The method of manufacturing the semiconductor device of claim 1, wherein each of the plurality of pads includes polytetrafluoroethylene combined with carbon (C).

7. A substrate processing apparatus comprising:
a housing that defines a processing region in which a substrate is processed;
a power supply source on the housing, the power supply source being configured to generate plasma;
a shower head in the housing and configured to supply the plasma to the processing region, the shower head including one or more first fastening holes;
an adapter between the power supply source and the shower head, the adapter being separated from the shower head;
a lid surrounding at least a part of the adapter, the lid being connected to the shower head through one or more fastening portions respectively inserted into the one or more first fastening holes; and
a plurality of pads between the shower head and the lid, wherein
each of the plurality of pads includes polytetrafluoroethylene, and
at least a part of the plurality of pads comes into contact with a bottom surface of the adapter.

8. The substrate processing apparatus of claim 7, wherein
each of the plurality of pads includes a second fastening hole that overlaps a corresponding first fastening hole into which a corresponding fastening portion is inserted,
the corresponding first fastening hole is among the one or more first fastening holes, and
the corresponding fastening portion is among the one or more fastening portions.

9. The substrate processing apparatus of claim 7, wherein
the shower head includes a trench,
each of the plurality of pads includes a first portion on the shower head and a second portion in the trench of the shower head, and
a shape of the second portion is elliptical from a planar viewpoint.

10. The substrate processing apparatus of claim 9, wherein the first fastening hole is offset from a center of the second portion.

11. The substrate processing apparatus of claim 9, wherein
from a planar viewpoint, a width of a cross-section of the trench is greater than a width of a cross-section of a first fastening hole among the one or more first fastening holes.

12. The substrate processing apparatus of claim 7, wherein at least a part of the plurality of pads covers a part of a side wall of the shower head.

13. The substrate processing apparatus of claim 7, wherein each of the plurality of pads includes polytetrafluoroethylene combined with carbon (C).

14. The substrate processing apparatus of claim 7, wherein at least a part of the plurality of pads covers the one or more first fastening holes.

15. The substrate processing apparatus of claim 7, wherein each of the plurality of pads corresponds to one of the first fastening holes.

16. The substrate processing apparatus of claim 7, wherein a vertical distance from an upper surface of the shower head to an upper surface of a corresponding one of the plurality of pads is the same as a vertical distance from the upper surface of the shower head to a lower surface of the adapter.

17. A substrate processing apparatus comprising:
a housing that defines a processing region in which a substrate is processed;
a power supply source on the housing, the power supply source being configured to generate plasma;
a shower head in the housing and configured to supply the plasma to the processing region, and the shower head including a plurality of first fastening holes;
an adapter between the power supply source and the shower head, the adapter being separated from the shower head;
a lid surrounding at least a part of the adapter, the lid being connected to the shower head through a fastening portion inserted into the plurality of first fastening holes, and the lid not being in contact with the shower head; and
a plurality of pads between the lid and the shower head, wherein
the pads include a horizontal portion and a vertical portion,
the horizontal portion extends in a horizontal direction and comes into contact with an upper surface of the shower head, and
the vertical portion extends in a vertical direction and comes into contact with a side surface of the shower head.

18. The substrate processing apparatus of claim 17, wherein
the shower head includes a trench,
each of the plurality of pads includes a second fastening hole and a second portion,
the fastening portion is inserted the second fastening hole, and
the second portion which protrudes from the horizontal portion in the vertical direction and is in the trench of the shower head, and
the second fastening hole is offset from a center of the second portion.

19. The substrate processing apparatus of claim 17, wherein each of the plurality of pads includes polytetrafluoroethylene or polytetrafluoroethylene combined with carbon (C).

20. The substrate processing apparatus of claim 17, wherein at least a part of the plurality of pads comes into contact with a bottom surface of the adapter.
